(19) United States
(12) Patent Application Publication
(10) Pub. No.: US 2008/0238570 A1
(43) Pub. Date: Oct. 2, 2008

(54) Spst Switch, Spdt Switch and Mpmt Switch

(76) Inventors: Masatake Hangai, Tokyo (JP); Morishige Hieda, Tokyo (JP); Moriyasu Miyazaki, Tokyo (JP)

Correspondence Address: BIRCH STEWART KOLASCH & BIRCH, PO BOX 747, FALLS CHURCH, VA, 22040-0747, US

(21) Appl. No.: 10/586,748

(22) PCT Filed: Mar. 24, 2004
(86) PCT No.: PCT/JP2004/004015

§ 371 Date: Jul. 21, 2006

(51) Int. Cl. H01P 1/15; H03K 17/00

(52) U.S. Cl. 333/103; 327/404

(57) ABSTRACT

A single pole single throw switch for controlling propagation of a high frequency signal between an input terminal (11a) and an output terminal (11b). First FET switches (14a, 14b) in which drains and sources of FETs (12a, 12b) are connected in parallel with inductors (13a, 13b) are connected in parallel. Each FET (12a, 12b) is switched between on state and off state by a voltage being applied to the gate thereof. At the frequency of the high frequency signal, each inductor (13a, 13b) connected with off capacitor of each FET (12a, 12b) resonates in parallel.

### TECHNICAL FIELD

The present invention relates to a single-pole single-throw (SPST) switch, a single-pole double-throw (SPDT) switch and a multiple-pole multiple-throw (MPMT) switch for controlling propagation of a high frequency signal.

### BACKGROUND ART

FIG. 1 is a circuit diagram showing a conventional SPDT switch shown in “High-power microwave transmit-receive switch with series and shunt GaAs FETs”, IEICE Trans. ELECTRON, February 1992.

The SPDT switch as shown in FIG. 1 has an input terminal 1a, output terminal 1b, output terminal 1c, FET (field-effect transistor) 2a, FET 2b, inductor 3a, inductor 3b, line 4 and ground 5. The FET 2a has its drain connected to the input terminal 1a, and its source connected to the output terminal 1c. The inductor 3a has its first terminal connected to the input terminal 1a, and its second terminal connected to the output terminal 1c. The line 4 has its first terminal connected to the input terminal 1a, and its second terminal connected to the output terminal 1b. The FET 2b has its drain connected to the output terminal 1b, and its source connected to the ground 5. The inductor 3b has its first terminal connected to the output terminal 1b, and its second terminal connected to the ground 5.

Next the operation will be described.

In FIG. 1, the FET 2a and FET 2b operate as switches for switching between the ON state and OFF state in response to a voltage applied to their gates. When a gate voltage with the same potential as the drain voltage and source voltage is applied to the gate of the FET 2a, the FET 2a is brought into the ON state and exhibits a resistance property. On the other hand, when a voltage less than the pinch-off voltage is applied to the gate of the FET 2a, the FET 2a is brought into the OFF state and exhibits a capacitance property. The FET 2b operates in the same manner.

FIG. 2 is an equivalent circuit diagram when the FET 2a and FET 2b in FIG. 1 are brought into the OFF state. As shown in FIG. 2, when the FET 2a is brought into the OFF state, a state arises in which a parallel connection of an OFF capacitance 9 and an OFF resistance 10 is connected in series with a parasitic inductor 8 between the drain or source 6a and the source or drain 6b of the FET 2a. The same state arises when the FET 2b is brought into the OFF state.

FIG. 3 is an equivalent circuit diagram when the FET 2a and FET 2b in FIG. 1 are brought into an ON state. As shown in FIG. 3, when the FET 2a is brought into the ON state, a state arises in which the ON resistance 7 and parasitic inductor 8 are connected in series between the drain or source 6a and the source or drain 6b of the FET 2a. The same state arises when the FET 2b is brought into the ON state.

In FIG. 1, consider the case where the FET 2a and FET 2b are brought into the OFF state, that is, when the equivalent circuit diagram of the FET 2a and FET 2b is FIG. 2. At the frequency f1 used by the SPDT switch, when the reactance component of the parasitic inductor 8 is small enough as compared with the reactance component of the OFF capacitance 9, and the OFF resistance 10 is sufficiently large, and when the relationship holds of f1=1/√(capacitance of OFF capacitance 9 of FET 2a)×(inductance of inductor 3a)=1/√(capacitance of OFF capacitance 9 of FET 2b)×(inductance of inductor 3b), the impedance of the output terminal 1b seen from the input terminal 1a becomes low, and the impedance of the output terminal 1c seen from the input terminal 1a becomes high. In this case, the high frequency signal input through the input terminal 1a is fed to the output terminal 1b.

In addition, consider the case where the FET 2a and FET 2b are brought into the ON state in FIG. 1, that is, when the equivalent circuit diagram of the FET 2a and FET 2b is FIG. 3. In this case, the impedance of the output terminal 1b seen from the input terminal 1a becomes high, and the impedance of the output terminal 1c seen from the input terminal 1a becomes low. Thus, the high frequency signal input through the input terminal 1a is fed to the output terminal 1c.

With the foregoing configuration, the conventional SPDT switch has the following problem. When the gate width of the FET 2a and FET 2b is increased to achieve high withstanding power, the reactance component of the parasitic inductor 8 comes to be not negligible as compared with the reactance component of the OFF capacitance 9, and the OFF resistance 10 becomes small. Accordingly, when the FET 2a and FET 2b are brought into the OFF state, the propagation loss of the high frequency signal propagating from the input terminal 1a to the output terminal 1b increases, which presents a problem of reducing the isolation of the high frequency signal from the input terminal 1a to the output terminal 1c.

Although the conventional technique is described by way of example of the SPDT switch, an SPST switch or MPMT switch has the same problem.

The present invention is implemented to solve the foregoing problem. Therefore it is an object of the present invention to provide an SPST switch, SPDT switch and MPMT switch having characteristics of being able to achieve high withstanding power, to reduce propagation loss of the high frequency signal, and to prevent the reduction in the isolation.

### DISCLOSURE OF THE INVENTION

According to one aspect of the present invention, there is provided an SPST (single-pole single-throw) switch for controlling propagation of a high frequency signal between an input terminal and an output terminal, the SPST switch comprising: a plurality of first field-effect transistor switches connected in parallel, each of which includes a field-effect transistor having its drain and source connected in parallel with an inductor, wherein each of the field-effect transistors has its ON state and OFF state changed by a voltage applied to a gate of each of the field-effect transistors, and each of the field-effect transistors has its OFF capacitance cause parallel resonance with the inductor connected at a frequency of the high frequency signal.

According to the present invention, an advantage is obtained of being able to achieve high withstanding power, and to reduce the propagation loss of the high frequency signal from the input terminal to the output terminal, and to prevent reduction in the isolation of the high frequency signal from the input terminal to the output terminal.

### BRIEF DESCRIPTION OF THE DRAWINGS

FIG. 1 is a circuit diagram showing a conventional SPDT switch;

FIG. 2 is an equivalent circuit diagram when field-effect transistors in FIG. 1 are brought into the OFF state;

FIG. 3 is an equivalent circuit diagram when the field-effect transistors in FIG. 1 are brought into the ON state;

FIG. 4 is a circuit diagram showing a configuration of an SPST switch of an embodiment 1 in accordance with the present invention;

FIG. 5 is an equivalent circuit diagram when field-effect transistors in FIG. 4 are brought into the OFF state;

FIG. 6 is an equivalent circuit diagram when the field-effect transistors in FIG. 4 are brought into the ON state;

FIG. 7 is a circuit diagram showing a configuration of an SPST switch of an embodiment 2 in accordance with the present invention;

FIG. 8 is an equivalent circuit diagram when field-effect transistors in FIG. 7 are brought into the OFF state;

FIG. 9 is an equivalent circuit diagram when the field-effect transistors in FIG. 7 are brought into the ON state;

FIG. 10 is a circuit diagram showing a configuration of an SPST switch of an embodiment 3 in accordance with the present invention;

FIG. 11 is an equivalent circuit diagram when the field-effect transistor in FIG. 10 is brought into the OFF state;

FIG. 12 is an equivalent circuit diagram when the field-effect transistor in FIG. 10 is brought into the ON state;

FIG. 13 is a circuit diagram showing a configuration of an SPST switch of an embodiment 4 in accordance with the present invention;

FIG. 14 is an equivalent circuit diagram when the field-effect transistor in FIG. 13 is brought into the OFF state;

FIG. 15 is an equivalent circuit diagram when the field-effect transistor in FIG. 13 is brought into the ON state;

FIG. 16 is a circuit diagram showing a configuration of an SPST switch of an embodiment 5 in accordance with the present invention;

FIG. 17 is an equivalent circuit diagram when field-effect transistors in FIG. 16 are brought into the OFF state;

FIG. 18 is an equivalent circuit diagram when the field-effect transistors in FIG. 16 are brought into the ON state;

FIG. 19 is a circuit diagram showing a configuration of an SPST switch of an embodiment 6 in accordance with the present invention;

FIG. 20 is an equivalent circuit diagram when field-effect transistors in FIG. 19 are brought into the OFF state;

FIG. 21 is an equivalent circuit diagram when the field-effect transistors in FIG. 19 are brought into the ON state;

FIG. 22 is a circuit diagram showing a configuration of an SPDT switch of an embodiment 7 in accordance with the present invention;

FIG. 23 is an equivalent circuit diagram when field-effect transistors in FIG. 22 are brought into the OFF state;

FIG. 24 is an equivalent circuit diagram when the field-effect transistors in FIG. 22 are brought into the ON state;

FIG. 25 is a circuit diagram showing a configuration of an MPMT switch of an embodiment 8 in accordance with the present invention; and

FIG. 26 is a table illustrating the operation of the MPMT switch of FIG. 25.

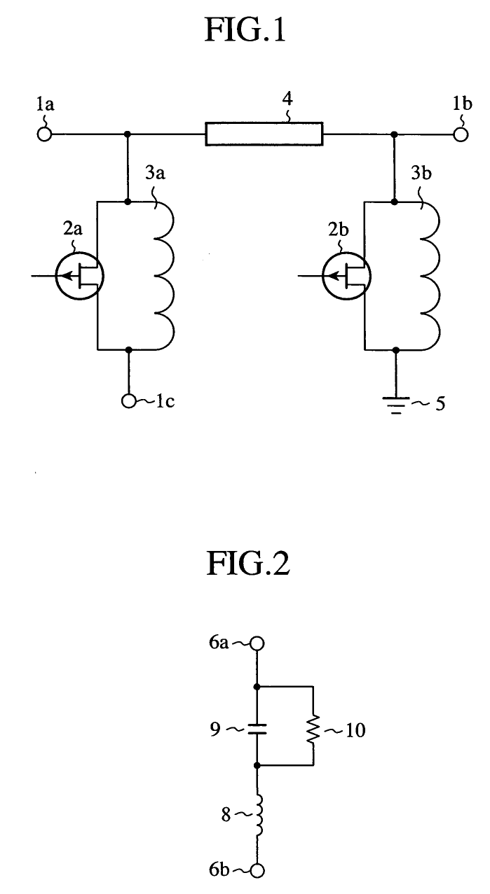

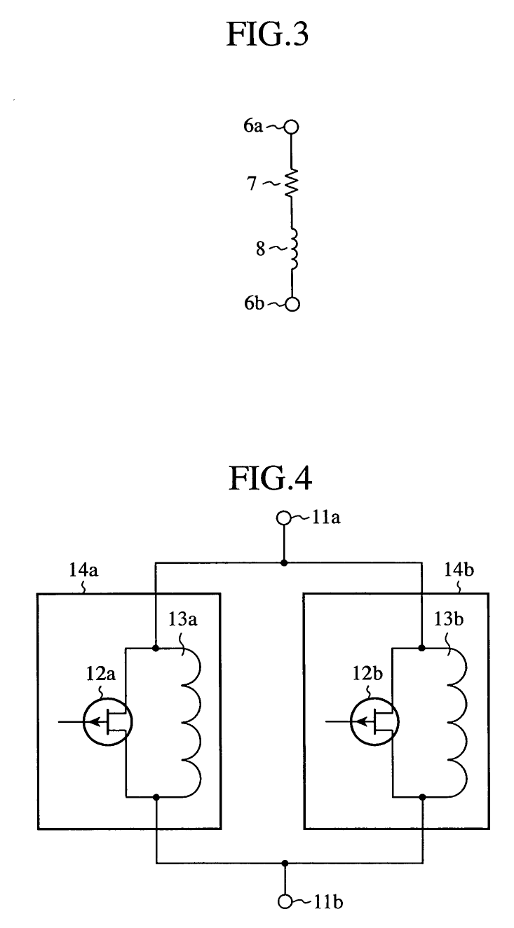

### BEST MODE FOR CARRYING OUT THE INVENTION

The best mode for carrying out the invention will now be described with reference to the accompanying drawings to explain the present invention in more detail.

### Embodiment 1

FIG. 4 is a circuit diagram showing a configuration of an SPST switch of an embodiment 1 in accordance with the present invention. The SPST switch shown in FIG. 4 has an input terminal 11a, output terminal 11b, FET (field-effect transistor) 12a, FET 12b, inductor 13a and inductor 13b. The parallel connection of the FET 12a and inductor 13a constitutes a first FET switch 14a, and the parallel connection of the FET 12b and inductor 13b constitutes a first FET switch 14b. The FET switches 14a and 14b have their first terminals connected to the input terminal 11a, and their second terminals connected to the output terminal 11b. Thus, the first FET switch 14a is connected in parallel with the first FET switch 14b in the present embodiment 1.

Connecting the two FETs 12a and 12b in parallel can halve their individual gate width to achieve the same withstanding power. Halving the individual gate width can make the reactance components of the parasitic inductors of the FETs 12a and 12b small enough as compared with the reactance component of the OFF capacitance at the frequency f used by the SPST switch, and make the OFF resistance large enough.

Here, the drains of the FET 12a and FET 12b can be connected to the input terminal 11a or output terminal 11b, and the sources of the FET 12a and FET 12b can be connected to the output terminal 11b or input terminal 11a.

Next the operation will be described.

In FIG. 4, the FET 2a and FET 2b operate as switches for switching between the ON state and OFF state by the voltages applied to the gates.

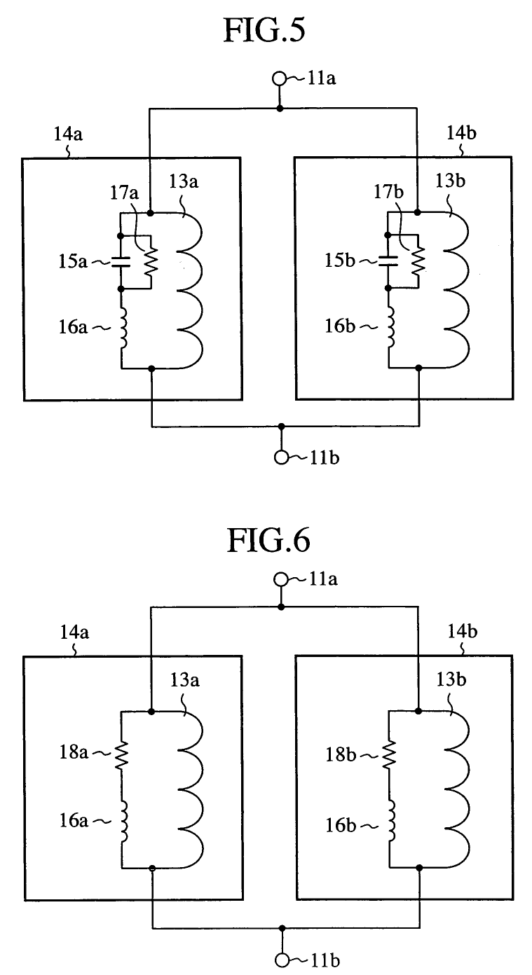

FIG. 5 is an equivalent circuit diagram when the FET 12a and FET 12b in FIG. 4 are brought into the OFF state. As shown in FIG. 5, when the FET 12a is brought into the OFF state, a state arises in which the OFF capacitance 15a and OFF resistance 17a which are connected in parallel are connected in series with the parasitic inductor 16a, and when the FET 12b is brought into the OFF state, a state arises in which the OFF capacitance 15b and OFF resistance 17b which are connected in parallel are connected in series with the parasitic inductor 16b.

At the frequency f used by the SPST switch, the reactance components of the parasitic inductors 16a and 16b are small enough as compared with the reactance components of the OFF capacitances 15a and 15b, and the OFF resistances 17a and 17b are large enough. Thus, when f=1/√(capacitance of OFF capacitance 15a)×(inductance of inductor 13a)=1/√(capacitance of OFF capacitance 15b)×(inductance of inductor 13b), that is, when the inductor 13a that will cause parallel resonance with the OFF capacitance 15a at the used frequency f is connected, and when the inductor 13b that will cause parallel resonance with the OFF capacitance 15b at the used frequency f is connected, the impedance of the output terminal 11b seen from the input terminal 11a becomes high. In this case, the high frequency signal input through the input terminal 11a is not fed to the output terminal 11b, and the isolation does not reduce of the high frequency signal from the input terminal 11a to the output terminal 11b.

FIG. 6 is an equivalent circuit diagram when the FET 12a and FET 12b in FIG. 4 are brought into the ON state. As shown in FIG. 6, when the FET 12a is brought into the ON state, a state arises in which the ON resistance 18a and parasitic inductor 16a are connected in series, and when the FET 12b is brought into the ON state, a state arises in which the ON resistance 18b and parasitic inductor 16b are connected in series.

In this case, since the first FET switches 14a and 14b are connected in parallel, the impedance of the output terminal 11b seen from the input terminal 11a becomes low. Thus, the high frequency signal input through the input terminal 11a is fed to the output terminal 11b, and the propagation loss of the high frequency signal from the input terminal 11a to the output terminal 11b can be reduced.

In the present embodiment 1, although the high frequency signal is controlled in such a manner that it is input through the input terminal 11a and is fed to the output terminal 11b, this is not essential. A configuration is also possible in which the high frequency signal is controlled in such a manner that it is input through the output terminal 11b and is fed to the input terminal 11a.

In addition, although the two first FET switches 14a and 14b are connected in parallel to halve the gate width of each of the FETs 12a and 12b in the present embodiment 1, this is not essential. A configuration is also possible in which two or more first FET switches are connected in parallel to narrow the gate width in accordance with the number of the FETs.

As described above, the present embodiment 1 can halve the gate width for achieving the same withstanding power by connecting the first FET switches 14a and 14b in parallel, and can make, at the used frequency f of the SPST switch, the reactance components of the parasitic inductors 16a and 16b of the FETs 12a and 12b small enough as compared with the reactance components of the OFF capacitances 15a and 15b, and make the OFF resistances 17a and 17b large enough. Thus, connecting the inductors 13a and 13b that will cause the parallel resonance with the OFF capacitances 15a and 15b offers an advantage of being able to achieve the high withstanding voltage and prevent the reduction in the isolation of the high frequency signal from the input terminal 11a to the output terminal 11b, and to reduce the propagation loss of the high frequency signal from the input terminal 11a to the output terminal 11b.

### Embodiment 2

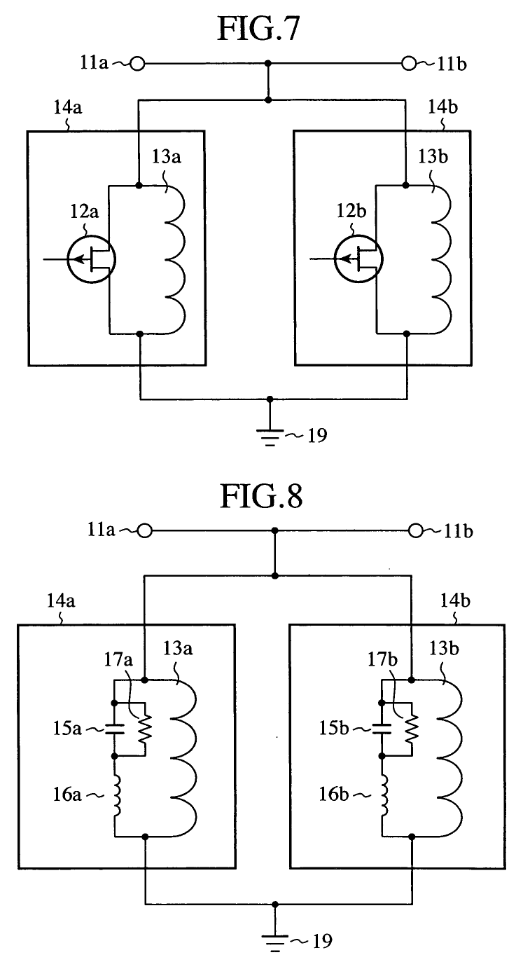

FIG. 7 is a circuit diagram showing a configuration of an SPST switch of an embodiment 2 in accordance with the present invention. As the SPST switch of the embodiment 1 shown in FIG. 4, the SPST switch shown in FIG. 7 has an input terminal 11a, output terminal 11b, FET 12a, FET 12b, inductor 13a and inductor 13b. The parallel connection of the FET 12a and inductor 13a constitutes a first FET switch 14a, and the parallel connection of the FET 12b and inductor 13b constitutes a first FET switch 14b. The embodiment 2, however, differs from the embodiment 1 in that the input terminal 11a and the output terminal 11b are connected directly, and in that the first FET switch 14a and first FET switch 14b have their first terminals connected to the input terminal 11a and output terminal 11b, and their second terminals connected to the ground 19. Thus, in the present embodiment 2, the first FET switch 14a is connected in parallel with the first FET switch 14b.

Connecting the two FETs 12a and 12b in parallel can halve their individual gate width to achieve the same withstanding power. Halving the individual gate width can make the reactance components of the parasitic inductors of the FETs 12a and 12b small enough as compared with the reactance component of the OFF capacitance at the frequency f used by the SPST switch, and make the OFF resistance large enough.

Here, the drains of the FET 12a and FET 12b can be connected to the input terminal 11a or the ground 19, and the sources of the FET 12a and FET 12b can be connected to the ground 19 or input terminal 11a.

Next the operation will be described.

In FIG. 7, the FET 2a and FET 2b operate as switches for switching between the ON state and OFF state by the voltages applied to the gates.

FIG. 8 is an equivalent circuit diagram when the FET 12a and FET 12b in FIG. 7 are brought into the OFF state. As shown in FIG. 8, when the FET 12a is brought into the OFF state, a state arises in which the OFF capacitance 15a and OFF resistance 17a which are connected in parallel are connected in series with the parasitic inductor 16a, and when the FET 12b is brought into the OFF state, a state arises in which the OFF capacitance 15b and OFF resistance 17b which are connected in parallel are connected in series with the parasitic inductor 16b.

In this case, at the frequency f used by the SPST switch, the reactance components of the parasitic inductors 16a and 16b are small enough as compared with the reactance components of the OFF capacitances 15a and 15b, and the OFF resistances 17a and 17b are large enough. Thus, when f=1/√(capacitance of OFF capacitance 15a)×(inductance of inductor 13a)=1/√(capacitance of OFF capacitance 15b)×(inductance of inductor 13b), that is, when the inductor 13a that will cause parallel resonance with the OFF capacitance 15a at the used frequency f is connected, and when the inductor 13b that will cause parallel resonance with the OFF capacitance 15b at the used frequency f is connected, the impedance of the ground 19 seen from the input terminal 11a becomes high. As a result, the high frequency signal input through the input terminal 11a is fed to the output terminal 11b, and the propagation loss of the high frequency signal can be reduced.

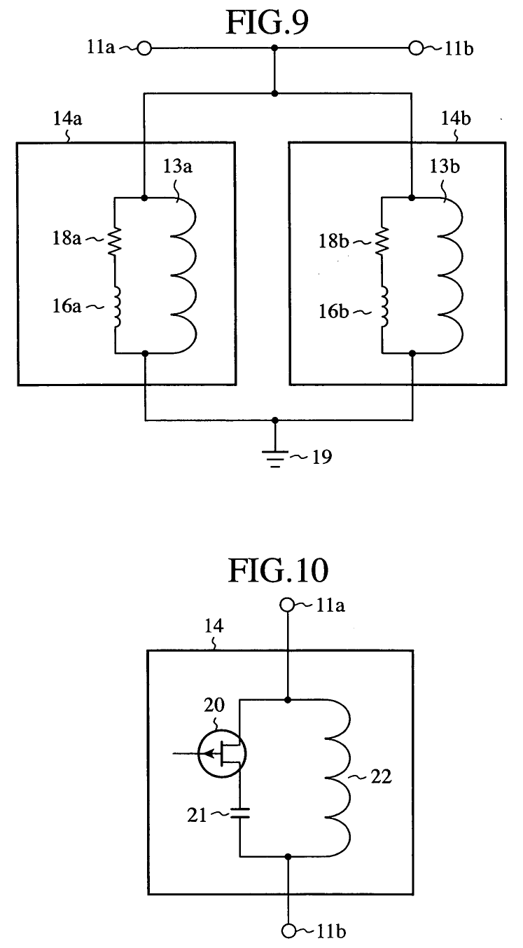

FIG. 9 is an equivalent circuit diagram when the FET 12a and FET 12b in FIG. 7 are brought into the ON state. As shown in FIG. 9, when the FET 12a is brought into the ON state, a state arises in which the ON resistance 18a and parasitic inductor 16a are connected in series, and when the FET 12b is brought into the ON state, a state arises in which the ON resistance 18b and parasitic inductor 16b are connected in series.

In this case, since the first FET switches 14a and 14b are connected in parallel, the impedance of the ground 19 seen from the input terminal 11a becomes low. Thus, the high frequency signal input through the input terminal 11a is propagated to the ground 19 without being fed to the output terminal 11b, and the isolation is not reduced of the high frequency signal from the input terminal 11a to the output terminal 11b.

In the present embodiment 2, although the high frequency signal is controlled in such a manner that it is input through the input terminal 11a and is fed to the output terminal 11b, this is not essential. A configuration is also possible in which the high frequency signal is controlled in such a manner that it is input through the output terminal 11b and is fed to the input terminal 11a.

In addition, although the two first FET switches 14a and 14b are connected in parallel to halve the gate width of each of the FETs 12a and 12b in the present embodiment 2, this is not essential. A configuration is also possible in which two or more first FET switches are connected in parallel to narrow the gate width in accordance with the number of the FETs.

As described above, the present embodiment 2 can halve the gate width for achieving the same withstanding power by connecting the first FET switches 14a and 14b in parallel, and can make, at the used frequency f of the SPST switch, the reactance components of the parasitic inductors 16a and 16b of the FETs 12a and 12b small enough as compared with the reactance components of the OFF capacitances 15a and 15b, and make the OFF resistances 17a and 17b large enough. Thus, connecting the inductors 13a and 13b that will cause the parallel resonance with the OFF capacitances 15a and 15b offers an advantage of being able to achieve the high withstanding voltage and to reduce the propagation loss of the high frequency signal from the input terminal 11a to the output terminal 11b, and to prevent the reduction in the isolation of the high frequency signal from the input terminal 11a to the output terminal 11b.

### Embodiment 3

FIG. 10 is a circuit diagram showing a configuration of an SPST switch of an embodiment 3 in accordance with the present invention. The SPST switch shown in FIG. 10 has an input terminal 11a, output terminal 11b, FET 20, capacitor 21 and inductor 22. A second FET switch 14, which consists of a series connection of the FET 20 and capacitor 21, and the inductor 22 connected in parallel with the series connection, has its first terminal connected to the input terminal 11a, and has its second terminal connected to the output terminal 11b.

Here, the drain of the FET 20 can be connected to the input terminal 11a or capacitor 21, and the source of the FET 20 can be connected to the capacitor 21 or input terminal 11a.

Next the operation will be described.

In FIG. 10, the FET 20 operates as a switch for switching between the ON state and OFF state by the voltage applied to the gate.

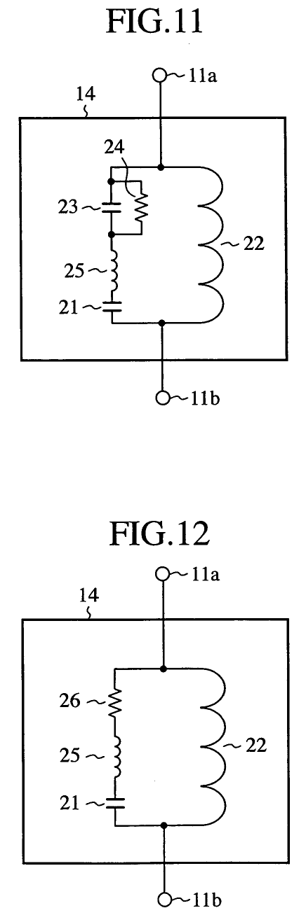

FIG. 11 is an equivalent circuit diagram when the FET 20 in FIG. 10 is brought into the OFF state. As shown in FIG. 11, when the FET 20 is brought into the OFF state, a state arises in which the OFF capacitance 23 and OFF resistance 24 which are connected in parallel are connected in series with the parasitic inductor 25.

When the relationship holds of f2=½π√(inductance of parasitic inductor 25)×(capacitance of capacitor 21) at the used frequency f2 of the SPST switch in the present embodiment 3, that is, when the capacitor 21 that will cause series resonance with the parasitic inductor 25 is connected, the parasitic inductor 25 that hinders the parallel resonance of the OFF capacitance 23 and inductor 22 is electrically canceled out. In addition, when the relationship holds of f2=1/√(capacitance of OFF capacitance 23)×(inductance of inductor 22) at the used frequency f2 of the SPST switch, that is, when the inductor 22 that will cause parallel resonance with the OFF capacitance 23, the impedance of the output terminal 11b seen from the input terminal 11a becomes high. In this case, the high frequency signal input through the input terminal 11a is not fed to the output terminal 11b. Thus, the isolation of the high frequency signal from the input terminal 11a to the output terminal 11b is not reduced.

FIG. 12 is an equivalent circuit diagram when the FET 20 in FIG. 10 is brought into the ON state. As shown in FIG. 12, when the FET 20 is brought into the ON state, a state arises in which the ON resistance 26 and the parasitic inductor 25 are connected in series.

When the relationship holds of f2=½π√(inductance of parasitic inductor 25)×(capacitance of capacitor 21), that is, when the capacitor 21 that will cause series resonance with the parasitic inductor 25 is connected, the impedance of the output terminal 11b seen from the input terminal 11a becomes low. In this case, the high frequency signal input through the input terminal 11a is fed to the output terminal 11b, and the propagation loss of the high frequency signal can be reduced.

Here, the inductance of the parasitic inductor 25 in the OFF state of the FET 20 as shown in FIG. 11 is equal to the inductance of parasitic inductor 25 in the ON state of the FET 20 as shown in FIG. 12. In addition, the values of the capacitance of capacitor 21 that will cause the series resonance with the parasitic inductor 25 in the OFF state and in the ON state of the FET 20 are equal.

In the present embodiment 3, although the high frequency signal is controlled in such a manner that it is input through the input terminal 11a and is fed to the output terminal 11b, this is not essential. A configuration is also possible in which the high frequency signal is controlled in such a manner that it is input through the output terminal 11b and is fed to the input terminal 11a.

As described above, even when the gate width of the FET 20 is increased to provide the SPST switch with the high withstanding power, the present embodiment 3 offers an advantage of being able to prevent the reduction in the isolation of the high frequency signal from the input terminal 11a to the output terminal 11b, and to reduce the propagation loss of the high frequency signal from the input terminal 11a to the output terminal 11b by connecting the capacitor 21 that will cause the series resonance with the parasitic inductor 25 of the FET 20 at the used frequency f2 of the SPST switch, and by connecting the inductor 22 that will cause the parallel resonance with the capacitance of the OFF capacitance 23 of the FET 20 at the used frequency.

### Embodiment 4

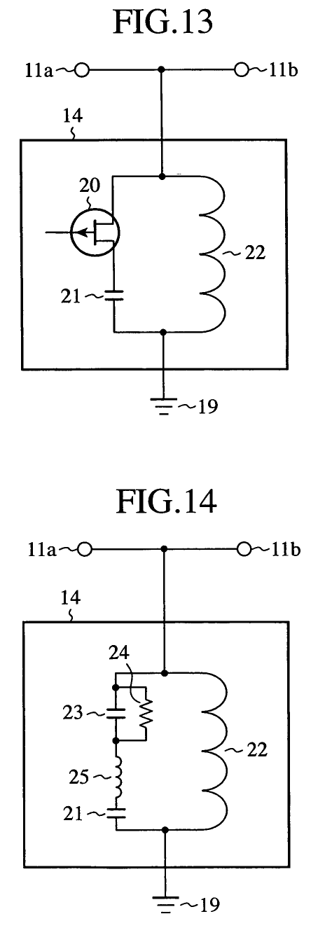

FIG. 13 is a circuit diagram showing a configuration of an SPST switch of an embodiment 4 in accordance with the present invention. As the SPST switch of the embodiment 3 as shown in FIG. 10, the SPST switch shown in FIG. 13 has an input terminal 11a, output terminal 11b, FET 20, capacitor 21 and inductor 22. The embodiment 4, however, differs from the embodiment 3 in that the input terminal 11a and the output terminal 11b are connected directly, and in that the second FET switch 14, which consists of a series connection of the FET 20 and capacitor 21 and the inductor 22 connected in parallel with the series connection, has its first terminal connected to the input terminal 11a and output terminal 11b, and has its second terminal connected to the ground 19.

Here, the drain of the FET 20 can be connected to the input terminal 11a or capacitor 21, and the source of the FET 20 can be connected to the capacitor 21 or input terminal 11a.

Next the operation will be described.

In FIG. 13, the FET 20 operates as a switch for switching between the ON state and OFF state by the voltage applied to the gate.

FIG. 14 is an equivalent circuit diagram when the FET 20 in FIG. 13 is brought into the OFF state. As shown in FIG. 14, when the FET 20 is brought into the OFF state, a state arises in which the OFF capacitance 23 and OFF resistance 24 which are connected in parallel are connected in series with the parasitic inductor 25.

When the relationship holds of f3=½π√(inductance of parasitic inductor 25)×(capacitance of capacitor 21) at the used frequency f3 of the SPST switch in the present embodiment, that is, when the capacitor 21 that will cause series resonance with the parasitic inductor 25 of the FET 20 is connected, the parasitic inductor 25 that hinders the parallel resonance of the OFF capacitance 23 and inductor 22 is electrically canceled out. In addition, when the relationship holds of f3=1/√(capacitance of OFF capacitance 23)×(inductance of inductor 22) at the used frequency f3 of the SPST switch, that is, when the inductor 22 that will cause parallel resonance with the OFF capacitance 23 of the FET 20 is connected, the impedance of the ground 19 seen from the input terminal 11a becomes high. In this case, the high frequency signal input through the input terminal 11a is fed to the output terminal 11b, and the propagation loss of the high frequency signal can be reduced.

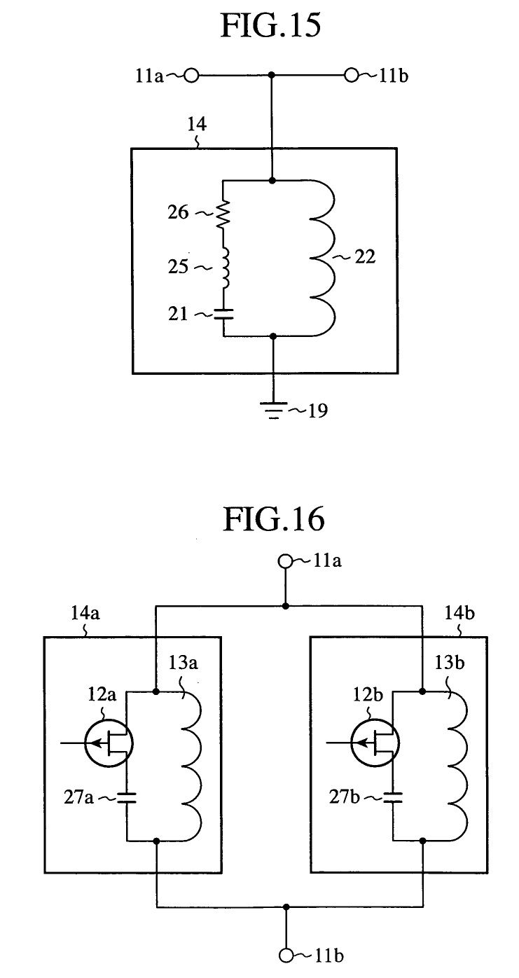

FIG. 15 is an equivalent circuit diagram when the FET 20 in FIG. 13 is brought into the ON state. As shown in FIG. 15, when the FET 20 is brought into the ON state, a state arises in which the ON resistance 26 and the parasitic inductor 25 are connected in series.

When the relationship holds of f3=½π√(inductance of parasitic inductor 25)×(capacitance of capacitor 21), that is, when the capacitor 21 that will cause series resonance with the parasitic inductor 25 of the FET 20 is connected, the impedance of the ground 19 seen from the input terminal 11a becomes low. In this case, the high frequency signal input through the input terminal 11a propagates to the ground 19 without being fed to the output terminal 11b, and the isolation of the high frequency signal from the input terminal 11a to the output terminal 11b is not reduced.

Here, the inductance of the parasitic inductor 25 in the OFF state of the FET 20 as shown in FIG. 14 is equal to the inductance of parasitic inductor 25 in the ON state of the FET 20 as shown in FIG. 15. In addition, the values of the capacitance of capacitor 21 that will cause the series resonance with the parasitic inductor 25 in the OFF state and in the ON state of the FET 20 are equal.

In the present embodiment 4, although the high frequency signal is controlled in such a manner that it is input through the input terminal 11a and is fed to the output terminal 11b, this is not essential. A configuration is also possible in which the high frequency signal is controlled in such a manner that it is input through the output terminal 11b and is fed to the input terminal 11a.

As described above, even when the gate width of the FET 20 is increased to provide the SPST switch with the high withstanding power, the present embodiment 4 offers an advantage of being able to reduce the propagation loss of the high frequency signal from the input terminal 11a to the output terminal 11b, and to prevent the reduction in the isolation of the high frequency signal from the input terminal 11a to the output terminal 11b by connecting the capacitor 21 that will cause the series resonance with the parasitic inductor 25 at the used frequency f3 of the SPST switch, and by connecting the inductor 22 that will cause the parallel resonance with the OFF capacitance 23 at the used frequency.

### Embodiment 5

FIG. 16 is a circuit diagram showing a configuration of an SPST switch of an embodiment 5 in accordance with the present invention. The SPST switch as shown in FIG. 16, which employs parallel connection of the two second FET switches 14 of the embodiment 3 as shown in FIG. 10, has an input terminal 11a, output terminal 11b, FET 12a, FET 12b, inductor 13a, inductor 13b, capacitor 27a, and capacitor 27b. The second FET switch 14a, in which the serial connection of the FET 12a and capacitor 27a is connected in parallel with the inductor 13a, and the second FET switch 14b, in which the serial connection of the FET 12b and capacitor 27b is connected in parallel with the inductor 13b, have their first terminals connected to the input terminal 11a and their second terminals connected to the output terminal 11b.

Next the operation will be described.

In FIG. 16, the FET 2a and FET 2b operate as switches for switching between the ON state and OFF state by the voltages applied to the gates.

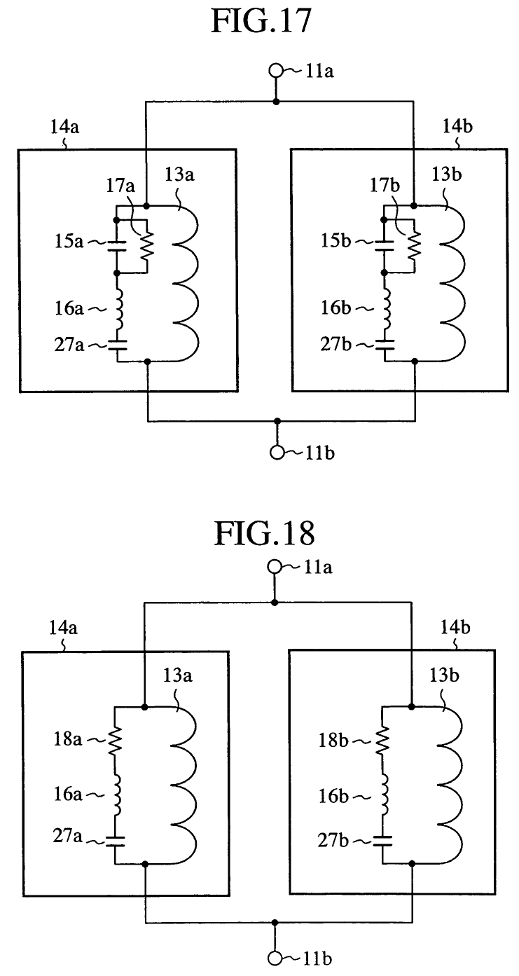

FIG. 17 is an equivalent circuit diagram when the FET 12a and FET 12b in FIG. 16 are brought into the OFF state. As shown in FIG. 17, when the FET 12a is brought into the OFF state, a state arises in which the OFF capacitance 15a and OFF resistance 17a which are connected in parallel are connected in series with the parasitic inductor 16a, and when the FET 12b is brought into the OFF state, a state arises in which the OFF capacitance 15b and OFF resistance 17b which are connected in parallel are connected in series with the parasitic inductor 16b.

Here, at the used frequency f4 of the SPST switch of the present embodiment, it is assumed that the relationship holds of f4=½π√(inductance of parasitic inductor 16a)×(capacitance of capacitor 27a)=½π√(inductance of parasitic inductor 16b)×(capacitance of capacitor 27b), that is, the capacitor 27a that will cause series resonance with the parasitic inductor 16a is connected to electrically cancel out the parasitic inductor 16a that hinders the parallel resonance of the OFF capacitance 15a and inductor 13a, and the capacitor 27b that will cause series resonance with the parasitic inductor 16b is connected to electrically cancel out the parasitic inductor 16b that hinders the parallel resonance of the OFF capacitance 15b and inductor 13b. In addition, at the used frequency f4 of the SPST switch, it is assumed that the relationship holds of f4=1/√(capacitance of OFF capacitance 15a)×(inductance of inductor 13a)=1/π√(capacitance of OFF capacitance 15b)×(inductance of inductor 13b), that is, the inductor 13a that will cause parallel resonance with the OFF capacitance 15a is connected, and the inductor 13b that will cause parallel resonance with the OFF capacitance 15b is connected. In this case, the impedance of the output terminal 11b seen from the input terminal 11a becomes high. Thus, the high frequency signal input through the input terminal 11a is not fed to the output terminal 11b, and the isolation of the high frequency signal from the input terminal 11a to the output terminal 11b is not reduced.

FIG. 18 is an equivalent circuit diagram when the FET 12a and FET 12b in FIG. 16 are brought into the ON state. As shown in FIG. 18, when the FET 12a is brought into the ON state, a state arises in which the ON resistance 18a and parasitic inductor 16a are connected in series, and when the FET 12b is brought into the ON state, a state arises in which the ON resistance 18b and parasitic inductor 16b are connected in series.

Here, at the used frequency f4 of the SPST switch, it is assumed that the relationship holds of f4=½π√(inductance of parasitic inductor 16a)×(capacitance of capacitor 27a)=½π√(inductance of parasitic inductor 16b)×(capacitance of capacitor 27b), that is, the capacitor 27a that will cause series resonance with the parasitic inductor 16a is connected, and the capacitor 27b that will cause series resonance with the parasitic inductor 16b is connected. In this case, the impedance of the output terminal 11b seen from the input terminal 11a becomes low. Thus, the high frequency signal input through the input terminal 11a is fed to the output terminal 11b, and the propagation loss of the high frequency signal can be reduced.

Here, the inductance of the parasitic inductors 16a and 16b in the OFF state of the FETs 12a and 12b shown in FIG. 17 is equal to the inductance of the parasitic inductors 16a and 16b in the ON state of the FETs 12a and 12b shown in FIG. 18. In addition, the values of the capacitances of the capacitors 27a and 27b that will cause the series resonance with the parasitic inductors 16a and 16b in the OFF state and in the ON state of the FETs 12a and 12b are equal.

In the present embodiment 5, although the high frequency signal is controlled in such a manner that it is input through the input terminal 11a and is fed to the output terminal 11b, this is not essential. A configuration is also possible in which the high frequency signal is controlled in such a manner that it is input through the output terminal 11b and is fed to the input terminal 11a.

In addition, although the two second FET switches 14a and 14b are connected in parallel in the present embodiment 5, two or more second FET switches can be connected in parallel.

As described above, even when the gate width of the FETs 12a and 12b is increased to provide the SPST switch with the high withstanding power, the present embodiment 5 offers an advantage of being able to reduce the propagation loss of the high frequency signal from the input terminal 11a to the output terminal 11b without reducing the isolation of the high frequency signal from the input terminal 11a to the output terminal 11b by connecting the capacitor 27a that will cause the series resonance with the parasitic inductor 16a at the used frequency f4 of the SPST switch, by connecting the capacitor 27b that will cause the series resonance with the parasitic inductor 16b, by connecting the inductor 13a that will cause the parallel resonance with the OFF capacitance 15a, and by connecting the inductor 13b that will cause the parallel resonance with the OFF capacitance 15b.

### Embodiment 6

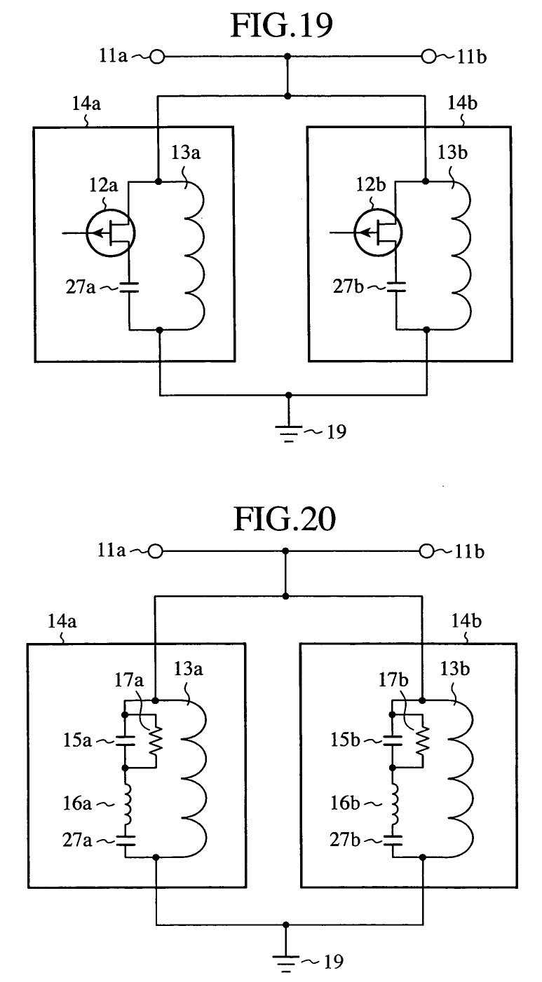

FIG. 19 is a circuit diagram showing a configuration of an SPST switch of an embodiment 6 in accordance with the present invention. The SPST switch as shown in FIG. 19, which employs parallel connection of the two second FET switches 14 of the embodiment 4 as shown in FIG. 13, has an input terminal 11a, output terminal 11b, FET 12a, FET 12b, inductor 13a, inductor 13b, capacitor 27a, capacitor 27b, and ground 19. The second FET switch 14a, in which the serial connection of the FET 12a and capacitor 27a is connected in parallel with the inductor 13a, and the second FET switch 14b, in which the serial connection of the FET 12b and capacitor 27b is connected in parallel with the inductor 13b, have their first terminals connected to the input terminal 11a and output terminal 11b, and their second terminals connected to the ground 19.

Next the operation will be described.

In FIG. 19, the FET 2a and FET 2b operate as switches for switching between the ON state and OFF state by the voltages applied to the gates.

FIG. 20 is an equivalent circuit diagram when the FET 12a and FET 12b in FIG. 19 are brought into the OFF state. As shown in FIG. 20, when the FET 12a is brought into the OFF state, a state arises in which the OFF capacitance 15a and OFF resistance 17a which are connected in parallel are connected in series with the parasitic inductor 16a, and when the FET 12b is brought into the OFF state, a state arises in which the OFF capacitance 15b and OFF resistance 17b which are connected in parallel are connected in series with the parasitic inductor 16b.

Here, at the used frequency f4 of the SPST switch of the present embodiment, it is assumed that the relationship holds of f4=½π√(inductance of parasitic inductor 16a)×(capacitance of capacitor 27a)=½π√(inductance of parasitic inductor 16b)×(capacitance of capacitor 27b), that is, the capacitor 27a that will cause series resonance with the parasitic inductor 16a is connected to electrically cancel out the parasitic inductor 16a that hinders the parallel resonance of the OFF capacitance 15a and inductor 13a, and the capacitor 27b that will cause series resonance with the parasitic inductor 16b is connected to electrically cancel out the parasitic inductor 16b that hinders the parallel resonance of the OFF capacitance 15b and inductor 13b. In addition, at the used frequency f4 of the SPST switch, it is assumed that the relationship holds of f4=1/√(capacitance of OFF capacitance 15a)×(inductance of inductor 13a)=1/√(capacitance of OFF capacitance 15b)×(inductance of inductor 13b), that is, the inductor 13a that will cause parallel resonance with the OFF capacitance 15a is connected, and the inductor 13b that will cause parallel resonance with the OFF capacitance 15b is connected. In this case, the impedance of the ground 19 seen from the input terminal 11a becomes high. Thus, the high frequency signal input through the input terminal 11a is fed to the output terminal 11b, and the propagation loss of the high frequency signal can be reduced.

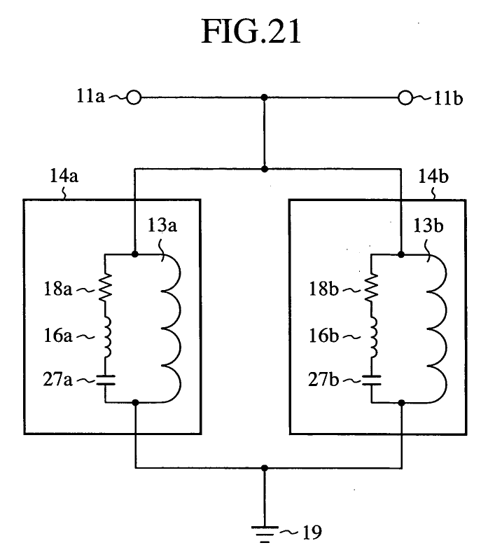

FIG. 21 is an equivalent circuit diagram when the FET 12a and FET 12b in FIG. 19 are brought into the ON state. As shown in FIG. 21, when the FET 12a is brought into the ON state, a state arises in which the ON resistance 18a and parasitic inductor 16a are connected in series, and when the FET 12b is brought into the ON state, a state arises in which the ON resistance 18b and parasitic inductor 16b are connected in series.

Here, at the used frequency f4 of the SPST switch, it is assumed that the relationship holds of f4=½π√(inductance of parasitic inductor 16a)×(capacitance of capacitor 27a)=½π√(inductance of parasitic inductor 16b)×(capacitance of capacitor 27b), that is, the capacitor 27a that will cause series resonance with the parasitic inductor 16a is connected, and the capacitor 27b that will cause series resonance with the parasitic inductor 16b is connected. In this case, the impedance of the output terminal 11b seen from the input terminal 11a becomes low. Thus, the high frequency signal input through the input terminal 11a is not fed to the output terminal 11b, and the isolation of the high frequency signal from the input terminal 11a to the output terminal 11b is not reduced.

Here, the inductance of the parasitic inductors 16a and 16b in the OFF state of the FETs 12a and 12b shown in FIG. 20 is equal to the inductance of the parasitic inductors 16a and 16b in the ON state of the FETs 12a and 12b shown in FIG. 21. In addition, the values of the capacitances of the capacitors 27a and 27b that will cause the series resonance with the parasitic inductors 16a and 16b in the OFF state and in the ON state of the FETs 12a and 12b are equal.

In the present embodiment 6, although the high frequency signal is controlled in such a manner that it is input through the input terminal 11a and is fed to the output terminal 11b, this is not essential. A configuration is also possible in which the high frequency signal is controlled in such a manner that it is input through the output terminal 11b and is fed to the input terminal 11a.

In addition, although the two second FET switches 14a and 14b are connected in parallel in the present embodiment 6, two or more second FET switches can be connected in parallel.

As described above, even when the gate width of the FETs 12a and 12b is increased to provide the SPST switch with the high withstanding power, the present embodiment 6 offers an advantage of being able to reduce the propagation loss of the high frequency signal from the input terminal 11a to the output terminal 11b, and to prevent the reduction in the isolation of the high frequency signal from the input terminal 11a to the output terminal 11b by connecting the capacitor 27a that will cause the series resonance with the parasitic inductor 16a at the used frequency f4 of the SPST switch, by connecting the capacitor 27b that will cause the series resonance with the parasitic inductor 16b, by connecting the inductor 13a that will cause the parallel resonance with the OFF capacitance 15a, and by connecting the inductor 13b that will cause the parallel resonance with the OFF capacitance 15b.

### Embodiment 7

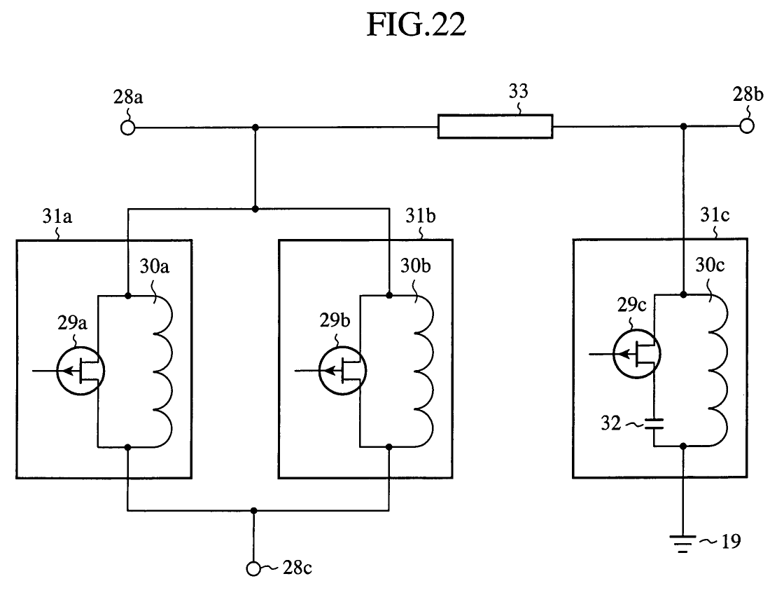

FIG. 22 is a circuit diagram showing a configuration of an SPDT switch of an embodiment 7 in accordance with the present invention. The SPDT switch as shown in FIG. 22 includes an input terminal 28a, output terminal 28b, output terminal 28c, FET 29a, FET 29b, FET 29c, inductor 30a, inductor 30b, inductor 30c, capacitor 32, line 33 and ground 19. A first FET switch 31a, in which the FET 29a and inductor 30a are connected in parallel, and a first FET switch 31b, in which the FET 29b and inductor 30b are connected in parallel, have their first terminals connected to the input terminal 28a, and their second terminals connected to the output terminal 28c. The line 33 has its first terminal connected to the input terminal 28a, and its second terminal connected to the output terminal 28b. A second FET switch 31c, in which a series connection of the FET 29c and capacitor 32 is connected in parallel with the inductor 30c, has its first terminal connected to the output terminal 28b, and its second terminal connected to the ground 19. Here, the line length of the line 33 is assumed to be ¼ wavelength at a used frequency f5.

In the present embodiment 7, the first FET switches 14a and 14b as shown in FIG. 4 of the embodiment 1 are used as the first FET switches 31a and 31b, and the second FET switch 14 as shown in FIG. 13 of the embodiment 4 is used as the second FET switch 31c.

Next the operation will be described.

In FIG. 22, the FET 29a, FET 29b and FET 29c operate as switches for switching between the ON state and OFF state by the voltages applied to the gates.

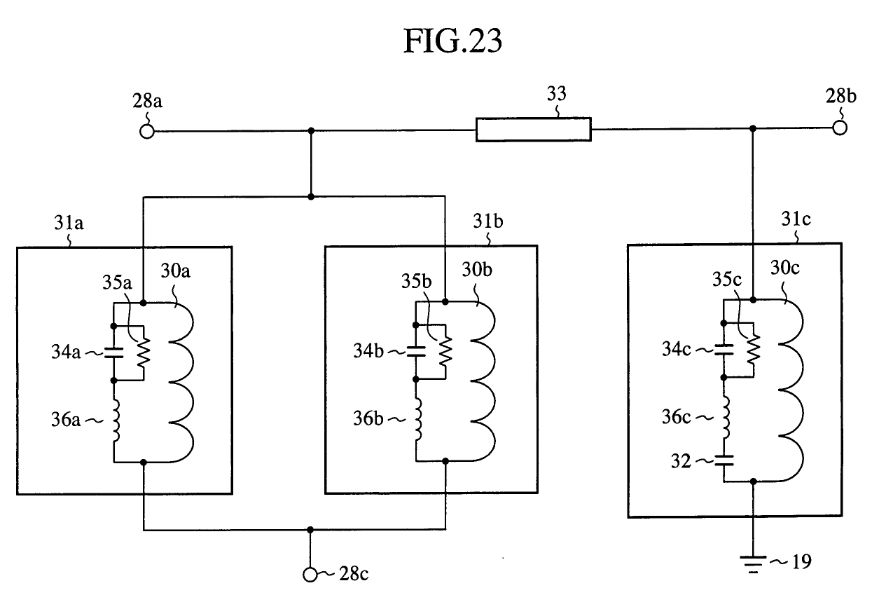

FIG. 23 is an equivalent circuit diagram when the FET 29a, FET 29b and FET 29c in FIG. 22 are brought into the OFF state. As shown in FIG. 23, when the FET 29a is brought into the OFF state, a state arises in which the OFF capacitance 34a and OFF resistance 35a which are connected in parallel are connected in series with the parasitic inductor 36a, when the FET 29b is brought into the OFF state, a state arises in which the OFF capacitance 34b and OFF resistance 35b which are connected in parallel are connected in series with the parasitic inductor 36b, and when the FET 29c is brought into the OFF state, a state arises in which the OFF capacitance 34c and OFF resistance 35c which are connected in parallel are connected in series with the parasitic inductor 36c.

It is assumed here that at the used frequency f5 of the SPDT switch of the present embodiment, the relationships hold of f5=½π√(inductance of parasitic inductor 36c)×(capacitance of capacitor 32), and f5=½π√(capacitance of OFF capacitance 34c)×(inductance of inductor 30c).

Connecting the two FETs 29a and 29b in parallel can halve their individual gate width to achieve the same withstanding power. Halving the individual gate width can make the reactance components of the parasitic inductors 36a and 36b of the FETs 29a and FET 29b small enough as compared with the reactance components of the OFF capacitances 34a and 34b at the frequency f5 used by the SPDT switch, and make the OFF resistances 35a and 35b large enough.

In addition, at the used frequency f5 of the SPDT switch, when the relationship holds of f5=1/√(capacitance of OFF capacitance 34a)×(inductance of inductor 30a)=1/√(capacitance of OFF capacitance 34b)×(inductance of inductor 30b), the impedance of the output terminal 28b seen from the input terminal 28a becomes low, and the impedance of the output terminal 28c seen from the input terminal 28a becomes high. In this case, the high frequency signal input through the input terminal 28a is fed to the output terminal 28b, and the propagation loss of the high frequency signal can be reduced. In contrast, the high frequency signal input through the input terminal 28a is not fed to the output terminal 28c, and the isolation of the high frequency signal from the input terminal 28a to the output terminal 28C is not reduced.

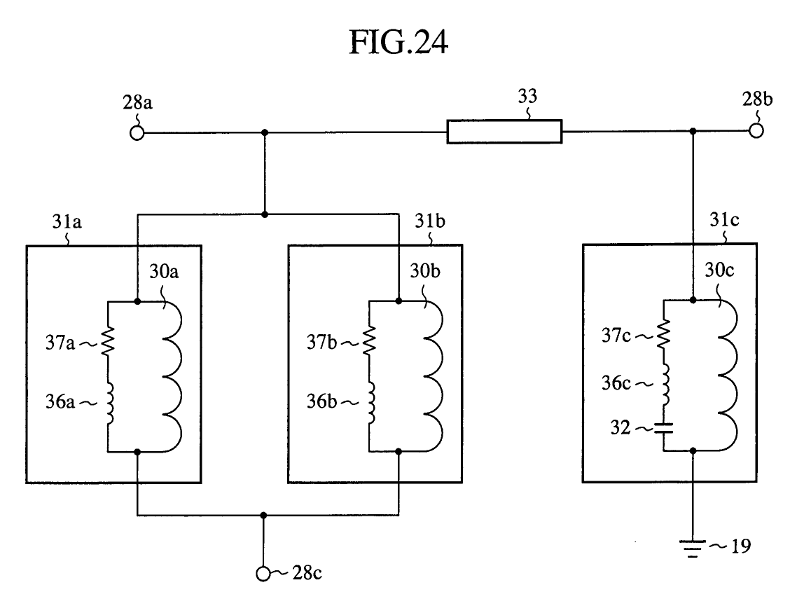

FIG. 24 is an equivalent circuit diagram when the FET 29a, FET 29b and FET 29c in FIG. 22 are brought into the ON state. As shown in FIG. 24, when the FET 29a is brought into the ON state, a state arises in which the ON resistance 37a and parasitic inductor 36a are connected in series, when the FET 29b is brought into the ON state, the ON resistance 37b and parasitic inductor 36b are connected in series, and when the FET 29c is brought into the ON state, the ON resistance 37c and parasitic inductor 36c are connected in series.

It is assume here that at the used frequency f5 of the SPDT switch, the relationship holds of f5=½π√(inductance of parasitic inductor 36c)×(capacitance of capacitor 32). Since the line length of the line 33 is ¼ wavelength at the used frequency f5, the impedance of the output terminal 28b seen from the input terminal 28a becomes high. In addition, since the first FET switches 31a and 31b are connected in parallel, the impedance of the output terminal 28c seen from the input terminal 28a becomes low. In this case, the high frequency signal input through the input terminal 28a is fed to the output terminal 28c, and the propagation loss of the high frequency signal can be reduced. At the same time, the high frequency signal input through the input terminal 28a is not fed to the output terminal 28b, and the isolation of the high frequency signal from the input terminal 28a to the output terminal 28b is not reduced.

Although the SPDT switch in the present embodiment 7 employs the first FET switches 31a and 31b and second FET switch 31c, the SPDT switch can be constructed from the first FET switches shown in the embodiments 1 and 2, or from the second FET switches shown in the embodiments 3, 4, 5, and 6, or from an appropriate combination of the first FET switches and second FET switches as shown in the embodiments 1-6.

As described above, the present embodiment 7 enables the SPDT switch to be constructed by combining the SPST switch from the embodiment 1 to the embodiment 6, thereby offering an advantage of being able to reduce the propagation loss of the high frequency signal from the input terminal 28a to the output terminal 28b or 28c, and to prevent the reduction in the isolation of the high frequency signal from the input terminal 28a to the output terminal 28b or 28c.

### Embodiment 8

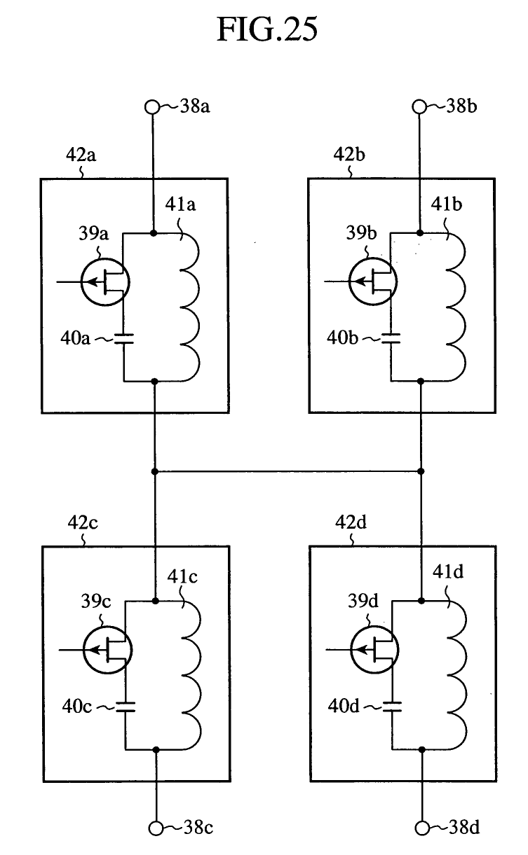

FIG. 25 is a circuit diagram showing a configuration of an MPMT switch of an embodiment 8 in accordance with the present invention. Although only the SPDT switch is described in connection with FIG. 22 of the foregoing embodiment 7, combining the SPST switches from the foregoing embodiment 1 to embodiment 6 can construct an MPMT switch as shown in FIG. 25, for example.

The MPMT switch as shown in FIG. 25 includes input terminals or output terminals 38a, 38b, 38c and 38d; FETs 39a, 39b, 39c and 39d; capacitors 40a, 40b, 40c and 40d; and inductors 41a, 41b, 41c and 41d. The FET 39a, capacitor 40a and inductor 41a constitute a second FET switch 42a; the FET 39b, capacitor 40b and inductor 41b constitute a second FET switch 42b; the FET 39c, capacitor 40c and inductor 41c constitute a second FET switch 42c; and the FET 39d, capacitor 40d and inductor 41d constitute a second FET switch 42d.

The second FET switches 42a, 42b, 42c and 42d have their first terminals connected to the input terminals or output terminals 38a, 38b, 38c and 38d, respectively, and their second terminals connected with each other.

Next the operation will be described.

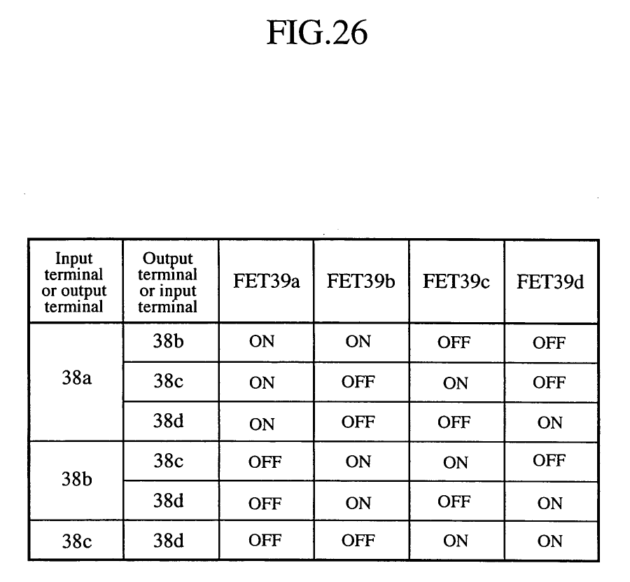

FIG. 26 is a table illustrating the operation of the MPMT switch of FIG. 25. Controlling the turning on and off of the individual FETs 39a, 39b, 39c and 39d enables the high frequency signal input through a designate input terminal to be fed to a designated output terminal.

Although the MPMT switch in the present embodiment 8 employs the second FET switches 42a, 42b, 42c and 42d, the MPMT switch can be constructed from the first FET switches as shown in the embodiment 1 or 2, or from the second FET switches as shown in the embodiment 3, 4, 5 or 6, or from an appropriate combination of the first FET switches and second FET switches as shown in the embodiments 1-6.

As described above, the present embodiment 8 can configure the MPMT switch by combining the SPST switches shown from the embodiment 1 to embodiment 6, thereby offering an advantage of being able to reduce the propagation loss of the high frequency signal from the input terminal to the output terminal, and to prevent the reduction in the isolation of the high frequency signal from the input terminal to the output terminal.

### INDUSTRIAL APPLICABILITY

As described above, the SPST switch, SPDT switch and MPMT switch in accordance with the present invention can reduce the propagation loss of the high frequency signal, and prevent the reduction of the isolation of the high frequency signal.

What is claimed is:

1. An SPST (single-pole single-throw) switch for controlling propagation of a high frequency signal between an input terminal and an output terminal, said SPST switch comprising:
a plurality of first field-effect transistor switches connected in parallel, each of which includes a field-effect transistor having its drain and source connected in parallel with an inductor, wherein
each of said field-effect transistors has its ON state and OFF state changed by a voltage applied to a gate of each of said field-effect transistors, and
each of said field-effect transistors has its OFF capacitance cause parallel resonance with said inductor connected at a frequency of the high frequency signal.

2. The SPST switch according to claim 1, wherein said plurality of first field-effect transistor switches are connected in parallel between the input terminal and output terminal.

3. The SPST switch according to claim 1, wherein
the input terminal and the output terminal are connected to each other; and
said plurality of first field-effect transistor switches are connected in parallel between the input terminal and a ground.

4. An SPST (single-pole single-throw) switch for controlling propagation of a high frequency signal between an input terminal and an output terminal, said SPST switch comprising:
a second field-effect transistor switch constructed by connecting an inductor in parallel with a series circuit of capacitor and a field-effect transistor that has its drain or source connected in series with the capacitor, wherein
said field-effect transistor has its ON state and OFF state changed by a voltage applied to a gate of said field-effect transistor, and
said field-effect transistor has its parasitic inductor and said capacitor cause series resonance, and has its OFF capacitance cause parallel resonance with said inductor.

5. The SPST switch according to claim 4, wherein said second field-effect transistor switch is connected between the input terminal and the output terminal.

6. The SPST switch according to claim 5, wherein a plurality of second field-effect transistor switches are connected in parallel between the input terminal and the output terminal.

7. The SPST switch according to claim 4, wherein
the input terminal and the output terminal are connected to each other; and
said second field-effect transistor switch is connected between the input terminal and a ground.

8. The SPST switch according to claim 7, wherein a plurality of second field-effect transistor switches are connected in parallel between the input terminal and the ground.

9. An SPDT (single-pole double-throw) switch for controlling propagation of a high frequency signal between an input terminal and two output terminals, said SPDT switch employing:
a plurality of first field-effect transistor switches as defined in claim 1, which are connected in parallel.

10. An SPDT (single-pole double-throw) switch for controlling propagation of a high frequency signal between an input terminal and two output terminals, said SPDT switch employing:
a second field-effect transistor switch as defined in claim 4.

11. An MPMT (multiple-pole multiple throw) switch for controlling propagation of a high frequency signal between a plurality of input terminals and a plurality of output terminals, said MPMT switch employing:
a plurality of first field-effect transistor switches as defined in claim 1, which are connected in parallel.

12. An MPMT (multiple-pole multiple throw) switch for controlling propagation of a high frequency signal between a plurality of input terminals and a plurality of output terminals, said MPMT switch employing:
second field-effect transistor switches as defined in claim 4.
